(19) United States
(12) Patent Application Publication
(10) Pub. No.: US 2017/0245404 A1
(43) Pub. Date: Aug. 24, 2017

(54) RF SHIELD WITH SELECTIVELY INTEGRATED SOLDER

(71) Applicant: Alpha Assembly Solutions Inc., Waterbury, CT (US)

(72) Inventors: Paul Joseph Koep, Madison, NJ (US); Michael Thomas Marczi, Chester, NJ (US); Karen Alice Tellefsen, Millington, NJ (US)

(21) Appl. No.: 15/426,320

(22) Filed: Feb. 7, 2017

Related U.S. Application Data
(60) Provisional application No. 62/297,295, filed on Feb. 19, 2016.

(51) Int. Cl. H05K 9/00; B23K 1/20; B23K 1/00; B23K 1/008; H05K 3/34; H05K 1/18

(52) U.S. Cl. CPC H05K 9/0024; H05K 9/0081; H05K 3/3494; H05K 1/181; B23K 1/0016; B23K 1/008; B23K 1/20; H05K 2201/10371; B23K 2201/42

(57) ABSTRACT

A shield for shielding a portion of an electronic component from undesirable emissions from neighboring components. The shield comprises a metal body configured to be attached to a substrate, and solder selectively applied to a lower portion of the metal body in manner that allows for both location and volume of the solder to be controlled. A bond is created between the solder and the metal body. The bond may be a metallurgical bond created by proximity of the solder to the at least one leg and sufficient heat and time to bring the solder to a melting temperature of the solder; or a diffusion bond created by heat and pressure. A method of attaching the shield to the substrate is also described.

### FIELD OF THE INVENTION

The present invention relates generally to methods of attaching shields for protecting electronic components from electromagnetic and radio frequency interference to substrates by means of the shield containing a selectively integrated solder.

### BACKGROUND OF THE DISCLOSURE

Electronic components, including, for example, resistors, capacitors, and semiconductor components, are often subjected to undesirable emissions, such as electromagnetic and radio frequency interference, from neighboring components that emit such interference and from external sources of electromagnetic and radio frequency interference. The emitted interference can adversely impact the performance and integrity of the electronic components because these emissions interfere with the operation of the electronic components by temporarily altering or distorting their essential characteristics, leading to adverse performance.

Various methods are used for protecting and shielding electronic components from the electromagnetic and radio frequency interference occurring in the proximate vicinity of the electronic component, such as printed circuit boards.

One such method of protecting electronic components from electromagnetic and radio frequency interference involves providing a shield, which serves to shield an area of a printed circuit board(s), or a volume associated therewith. The shield functions by either containing electromagnetic energy, for example, radiated RF signals, within the shielded volume or area, or the electromagnetic energy is excluded by the shield structure from the shielded volume or area.

This type of shielding is also used extensively in various devices where low signal level circuitry is receptive to being effected by stray electromagnetic fields emanating from AC power sources, including, for example, television receivers, direct satellite broadcast receivers, radio receivers such as FM and shortwave, or portions of audio systems.

A printed circuit board (PCB) is a common electronic component to which a shield can be beneficially applied, because PCBs enjoy widespread use in a number of electronic applications.

The term “printed circuit board” generally refers to circuit boards having electrical conductors disposed on one or more side of a substrate (e.g., a dielectric substrate). In one embodiment, a PCB will have openings or the like formed through the substrate to receive electrical leads of an electronic component that is mounted on one side of the PCB. The electrical leads extend through the openings to contact pads disposed on the other side of the PCB, and are typically soldered to the contact pads. PCBs may also be produced using surface mount technology, in which components or “packages” are mounted or placed directly on the surface of the PCB.

In order to shield electronic components on a PCB in electronic devices against electromagnetic radiation, a shielding in the form of an electrically conductive shield can or box can be placed on the PCB covering the electronic components. The highest level of shielding is achieved when a closed metal can with a free rim at downwardly extending side pieces is soldered to the PCB along the entire free edge of the metal can. In order to achieve good shielding, it is necessary that the solder joint between the shield can and the PCB be well controlled, preferably without leaving any unsoldered areas. If any areas remain unsoldered, the shielding efficiency is determined by the largest gap between the shield can and the PCB. Therefore, if gaps exist between the shield can and the PCB, the sizes of these gaps must be well defined.

The first step in a soldering process is to screen-print the PCB with solder paste at the desired areas. The thickness of the solder paste is determined by the thickness of the screen-printing stencil, which may be the same all over the PCB. There also exists “step up” and “step down” stencils, which can be used to change the thickness of the solder paste in specific areas on the PCB. However, limitations exist regarding the base thickness as well as the step up/step down thickness.

The next step is to place the electronic components on the PCB by a pick-and-place machine. The shield cans are normally placed on the PCB after the other components have been placed since the shield covers one or more of them.

In the last step of the process the PCB is heated in a soldering oven, whereby the applied solder paste melts, and all the components and the shield can(s) are soldered to the PCB. While the reflow oven is the most economical method, other methods including induction soldering and infrared soldering may also be used. Induction soldering and infrared soldering are used, for example, in step soldering in which the electronic components are first soldered using reflow soldering and the circuitry then undergoes electrical testing and the shields are attached in a secondary process.

Since small components, such as resistors and capacitors, require small volumes of solder paste and large components, such as shield cans, require large volumes of solder paste, the thickness of the screen-printing stencil must be set as a compromise between these two different needs. In addition, the thickness of the screen printing stencil is typically dictated by the tightest pitch component, because the tighter the pitch, the thinner the solder height required to prevent hot slump shorts between adjacent connections.

In addition, neither the shield nor the PCBs can be manufactured without inherent stress and, furthermore, the flatness of the PCB and the shield may be affected by the heat in the soldering oven (i.e., warping may occur). This means that there will always be a gap between the shield and the PCB. However, this is not a problem so long as the gap is filled with solder during heating. As described above, the thickness of the solder paste initially applied to the PCB is limited, meaning that the acceptable size of the gap is also limited, since it must be ensured that the gap becomes filled with solder. Furthermore, due to warping during heating, the size of the gap between the shield and the PCB increases with the size of the shield, and the size of the shield must therefore be limited for a given volume of solder in order to ensure that the gap can be filled with the pre-applied solder paste. Thus, the solder volume must be sufficient to maintain connection with both the shield legs and the PCB during the entire reflow process.

As integrated circuit lead pitch feature sizes continue to shrink, printing solder paste also requires the use of thinner stencils. The reduced solder height resulting from thinner stencils creates a challenge for the attachment strength of shields, because the volume requirement of the shield solder is not shrinking at the same rate as that of the integrated circuits. In addition, as the shield metal thickness is reduced, shield warping during reflow can increase, increasing the gap between the shield and the PCB.

In order to overcome the additional warping, the total amount of solder thickness required to successfully attach the shield legs to the printed circuit board must also increase. Sufficient solder volume is required to achieve certain reliability requirements such as drop shock, thermal cycling, and RF requirements. Insufficient solder volume results in reduced first pass yield, significant rework expense, and increased susceptibility to failure due to drop shock.

Poor solderability is a big problem in the electronics industry and is one of the most critical factors in the formation of reliable solder joints for printed circuit board assemblies as the solder interacts with the base metals, a good metallurgical bond is obtained and metallic continuity is established. This continuity is good for electrical and heat conductivity and is also important for strength. Good solderability or good spread occurs when the solder flows well to form a continuous, unbroken film free of any major voids or depressions.

One solution to insufficient solder volume for the shield involves the addition of discrete solder volume, either by means of “pick and place” of solder preforms, or by adding a step in the process to dispense additional solder paste. However, dispensing is a slow and inexact process, negatively impacting the cycle time of the entire process, and requires a significant investment in capital equipment. Pick and place of discrete solder preforms also represents an added cost, additional cycle time to place the preforms, and requires physical space near the target location to position the preform.

An attempt to overcome this problem has been to dispense extra solder paste to the area of the PCB where the shield can is to be positioned which requires an undesired extra manufacturing step. In addition, since dispense grade solder is typically only about 40% metal by volume, it may not be possible to achieve the desired solder volume by dispensing methods, especially in applications with extremely high density of electronic components, such as mobile phones.

The shield can typically comprises a substantially planar cover portion and one or more side portions connected to the substantially planar cover portion. For example, the substantially planar cover portion may be substantially square or rectangular and the one or more side portions may comprise four side portions. In addition, each of the one or more side portions may be of solid construction, ending in one or more tabs or legs or may comprise cutouts along a length of the one or more side portions that extend into the one or more tabs or legs to allow for joining of the shield to the underlying substrate. Thus, the one or more side portions (or the one or more legs are cutouts are configured for joining or mounting of the shield to the underlying substrate (which, as described herein, may be a PCB).

Other methods have also been suggested for improving the solder joint between the shield and the substrate.

One such method involves directly soldering of the shield to a ground plane of a PCB that is proximate to electromagnetic and radio frequency emitting components. However, a disadvantage to this method is that it is often time consuming to solder the shield to the ground plane of the PCB, resulting in increased manufacturing cost. Another disadvantage is that it can be cumbersome to apply the solder to the shield and then join the shield to the ground plane.

Another method involves the use of removable shields attached to shield clips coupled to the ground plane of the PCB, as described, for example, in U.S. Pat. Pub. No. 2008/0137319 to Bobrowski et al., the subject matter of which is herein incorporated by reference in its entirety.

U.S. Pat. No. 8,199,527 to Muranaga, the subject matter of which is herein incorporated by reference in its entirety, describes a manufacturing method in which the shield cover is dipped into cream solder and placed on the sheet substrate and then the shield cover is fixed to the sheet substrate by reflow process, which presents a challenge to consistently transfer a known amount of cream solder (or solder paste) onto the shield.

U.S. Pat. No. 6,796,485 to Seidler, the subject matter of which is herein incorporated by reference in its entirety, describes an electromagnetic shield which includes a shield body having an outer wall having a plurality of resilient fingers formed at a lower edge thereof and that includes a solder mass securely held mechanically by the fingers by being interleaved between the fingers. However, control of the placement of the solder mass can be inconsistent.

U.S. Pat. No. 7,383,977 to Fagrenius et al., the subject matter of which is herein incorporated by reference in its entirety, describes a method of attaching a shield can to a PCB that provides the rim of the shield can with an extra amount of solder by various methods.

Thus, it would be desirable to provide an improved means of attaching a shield to an underlying substrate in an efficient manner that overcomes the deficiencies of the prior art.

### BRIEF DESCRIPTION OF THE DRAWINGS

For a fuller understanding of the invention, reference is made to the following description taken in connection with the accompanying figures, in which:

FIG. 1 depicts a high resolution scanning electronic image of the intermetallic formed during the attaching of an SAC solder to a leg portion of an Alloy 770 RF shield in accordance with one embodiment of the present invention.

FIG. 2 depicts a shield leg partially loaded with solder.

FIG. 3 depicts an image of a shield leg fully loaded with solder.

FIG. 4A depicts an end view of a shield leg without solder at the end of the leg.

FIG. 4B depicts an end view of a shield leg with solder at the end of the leg.

FIG. 5 depicts a first view of a shield with solder at a distance from the edge of the leg of the shield.

FIG. 6 depicts another view of the shield with solder at a distance from the edge of the leg of the shield.

FIG. 7 depicts a view of a shield whose legs terminate on the top of pads on the PCB.

FIG. 8 depicts a view of a leg of a shield attached to the top of a pad of a PCB.

FIGS. 9A and 9B depict a front and side view of a shield with solder positioned on an inner side of the leg portion of the shield.

FIGS. 10A and 10B depict a front and side view of a shield with solder positioned on an outer side of the leg portion of the shield.

FIGS. 11A and 11B depict a front view and a side view of a shield with solder positioned on both planar sides (i.e., inner side and outer side) of the leg portion of the shield.

Also, while not all elements may be labeled in each figure, all elements with the same reference number indicate similar or identical parts.

### SUMMARY OF THE DISCLOSURE

It is an object of the present invention to provide an improved method of attaching a shield for protecting electronic components from electromagnetic and radio frequency interference to a substrate in an efficient manner.

It is another object of the present invention to provide an improved method of attaching a shield for protecting electronic components from electromagnetic and radio frequency interference to a printed circuit board in an efficient manner.

It is still another object of the present invention to provide an improved means of attaching a shield for protecting electronic components from electromagnetic and radio frequency interference to a substrate with improved solder volume and without the need for pick and place of solder preforms or the dispensing of additional solder paste.

In one embodiment, the present invention relates generally to a shield for protecting electronic components from electromagnetic and radio frequency interference comprising a metal body configured to be attached to a substrate and in which solder is applied to portions of the metal body to create a metallurgical bond between the solder and the metal body.

The present invention also relates generally to a shield that includes at least one leg configured to be attached to the substrate, with the metallurgical bond being formed between the shield and the solder on the at least one leg.

A method of controlling the location of solder on the shield to support non-planar soldering requirements, including the attachment of legs of the shield to the side of a PCB or other substrate is also disclosed.

In another embodiment, the present invention also relates generally to the dissolution of a higher melting point solder into a lower melting point solder using only the oven reflow temperature of the lower melting point solder.

Finally a method of attaching a shield to a substrate is also disclosed herein.

### DETAILED DESCRIPTION OF THE PREFERRED EMBODIMENTS

The present disclosure is directed to a shield for protecting electronic components from electromagnetic and radio frequency interference configured to provide a sufficient solder volume to overcome the insufficient solder volume problem described above.

In one embodiment, the shield includes a body configured to protect or shield electronic components and legs attached to or integral to the shield body, wherein the legs or tabs are configured to be attached to a substrate by soldering.

In one preferred embodiment, the substrate is a printed circuit board. Other similar substrates are also of being shielded by the shield of the invention using the method described herein. By providing a shield with solder already in place on one or more legs of the shield, reflow soldering of the shield can be accomplished without the need for additional process steps, including, for example, dispensing of solder paste, use of pick and place of solder preforms with solder paste, or dipping the shield into the solder paste.

In one embodiment and as described herein, solder is integrated onto specific regions (e.g., legs) of the shield that are the sites of attachment to the printed circuit board by means of a metallurgical or diffusion bond. The shield leg typically has a nominal thickness of between about 100 μm and about 300 μm, more preferably between about 120 and 200 μm and the thickness of the solder on the shield leg is generally in the range of about 100 to about 300 μm, more preferably about 150 to about 200 μm. A metallurgical bond is created between the solder and the shield material using a temperature-time profile. In the alternative, a diffusion bond is created by temperature in combination with pressure.

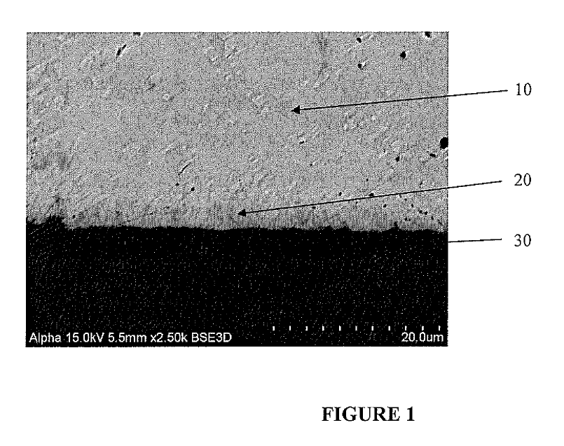

FIG. 1 shows a high resolution scanning electron microscope image of the intermetallic formed during the attachment process of an SAC solder 10 to an Alloy 770 RF shield metal 30. In one embodiment, the intermetallic 20 is formed on a leg of the RF shield that is to be attached to the circuit board.

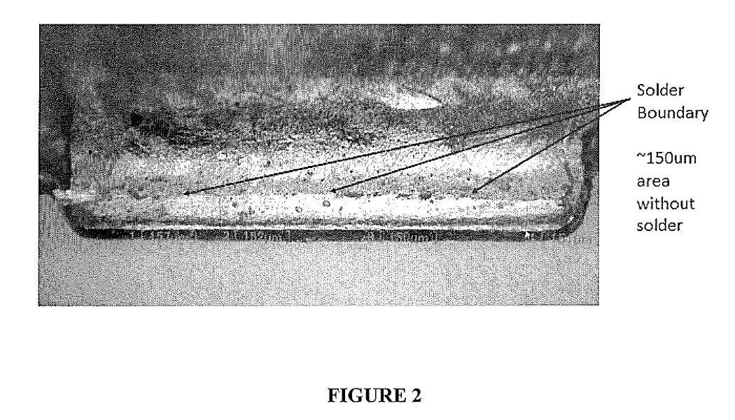

FIG. 2 shows a shield leg partially loaded with solder. The shield boundary can be seen as well as an area (approximately 150 μm) without solder.

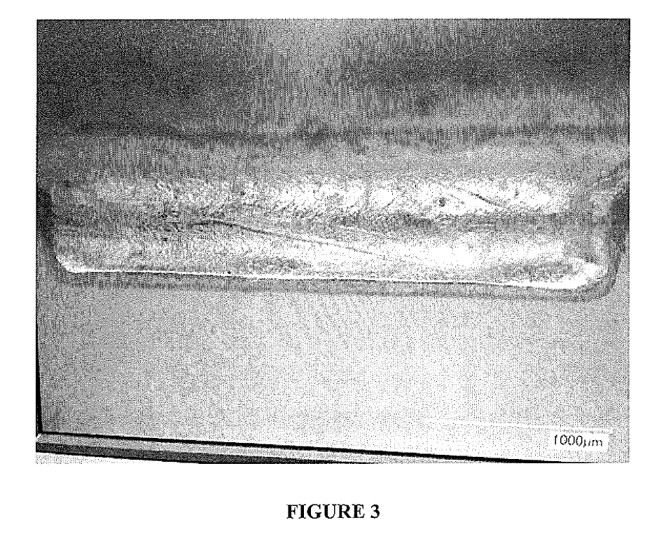

FIG. 3 shows a shield leg that has been fully loaded with solder.

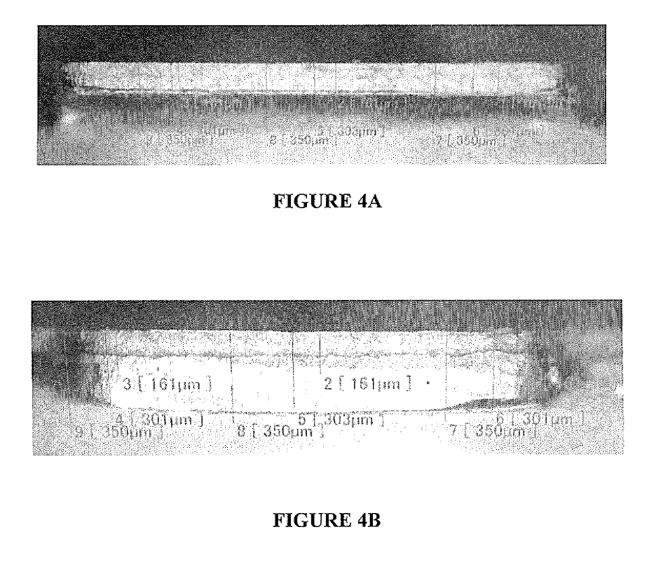

FIG. 4A shows an end view of a shield leg without solder on the end of the leg. The material of the shield leg has a nominal thickness of approximately 160 μm.

FIG. 4B shows an end view of a shield leg with solder on the end of the leg. The material of the shield leg has a nominal thickness of approximately 160 μm and the solder has a thickness of about 140-150 μm.

The metallurgical bond between the metal of the legs and the solder is created by proximity of the materials and sufficient heat and time to bring the solder to melting temperature. Thus, in one embodiment, the solder is selectively applied to the shield by printing, dispensing, placement, or jetting, using any combination of one or more of solder paste, solder preforms, flux paste, and molten solder, and then the shield with the solder applied thereon is placed in reflow furnace to create the metallurgical bond between the solder and the metal of the shield component. An alternative method is to place the shield legs partially in molten solder for a period of time sufficient to achieve wetting of the solder to the shield, and the desired spread of the solder upon the legs of the shield to a specific length. Once the modified shield has been created it can then be attached to the underlying electronic component which may be, for example, a printed circuit board.

Alternatively, heat and pressure may be used to create a diffusion bond between the solder and the shield metal in specific locations.

In a preferred embodiment, the shield has a quadrilateral cover shape and includes four peripheral side edges and a plurality of recesses or legs or tabs on each of the respective four peripheral side edges that are capable of being soldered to the substrate.

In one embodiment, the legs or tabs of the shield have integrated therein solder on a lower edge thereof, the solder forming an intermetallic bond with the metal of the tab or leg of the shield. The plurality of tabs or legs can extend up at least a portion of the four peripheral side edges depending on the needs of the customer. For example, the plurality of tabs or legs can extend up at least 5% of the depth of the peripheral side edge, or extend up at least about 10% of the depth of the peripheral side edge, or extend up at least about 25% of the depth of the peripheral side edge. In some embodiments and depending on the needs of the customer, the legs or tabs may extend up at least about 30% or at least about 40%, at least about 50%, or at least about 75% of the depth of the peripheral side edge.

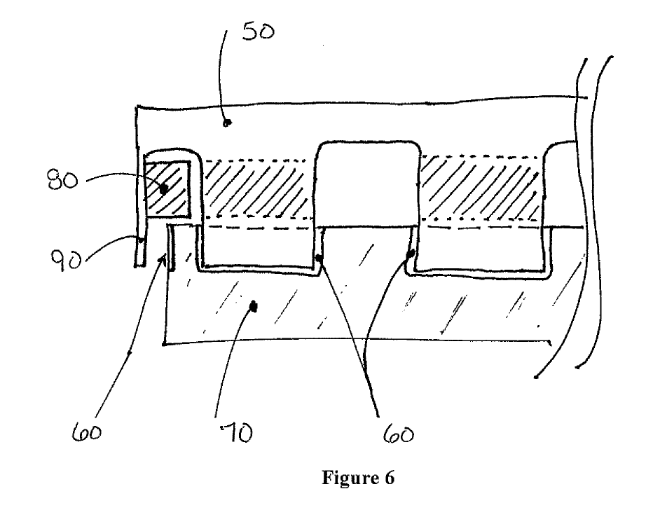

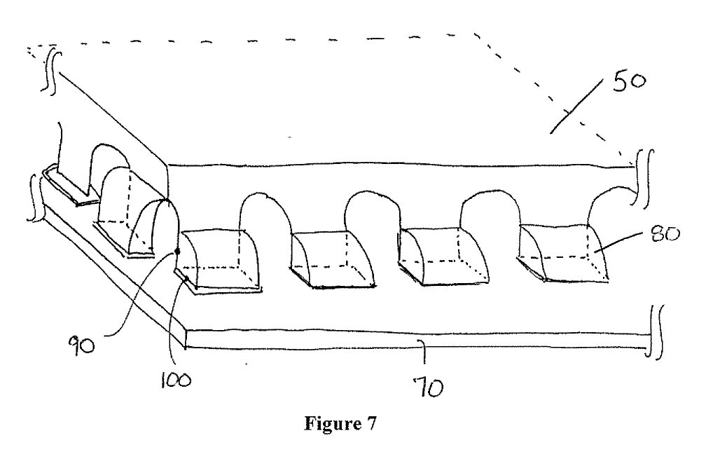

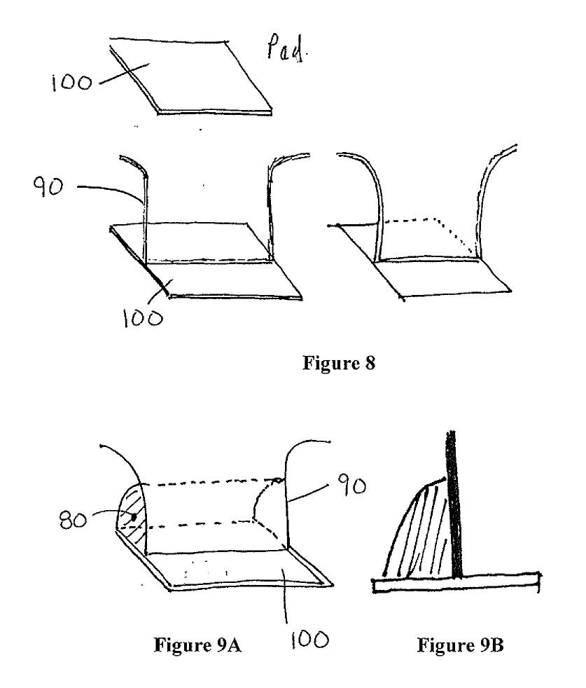

An example of this is shown in FIGS. 7 and 8, which depicts a shield 50 mounted on a PCB 70 comprising a plurality of pads 100. In this embodiment, the solder 80 is preferentially positioned towards a front (i.e., outside surface) of the legs 90. Thus, the shield 50 is attached to the PCB 70 by means of pads 100.

In another embodiment, the solder is positioned on the tabs or legs, but the solder terminates precisely at a distance from the lower end. The solder boundary location is critical to enable assembly of the shield whose legs are destined to be soldered to the side of a substrate or PCB. In this instance, the solder acts as a reservoir, and will be drawn down to provide the attachment of the shield leg to the side of the PCB, which is solderable with a plated surface.

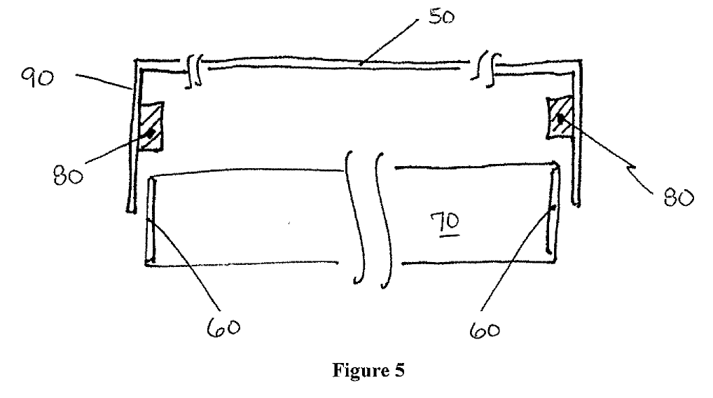

Thus, as seen in FIG. 5, the shield 50 may be attached to a plated sidewall 60 of a PCB 70. The solder 80 is positioned on a portion of the shield leg 90 above the plated side wall 60 of the PCB 70 and can then be drawn down upon reflow of the solder to create the bond between the shield leg 90 and the plated side wall 60 of the PCB 70. FIG. 6 shows another view of the shield of FIG. 5 in which the shield legs 90 are positioned over the plated side wall 60 of the PCB 70.

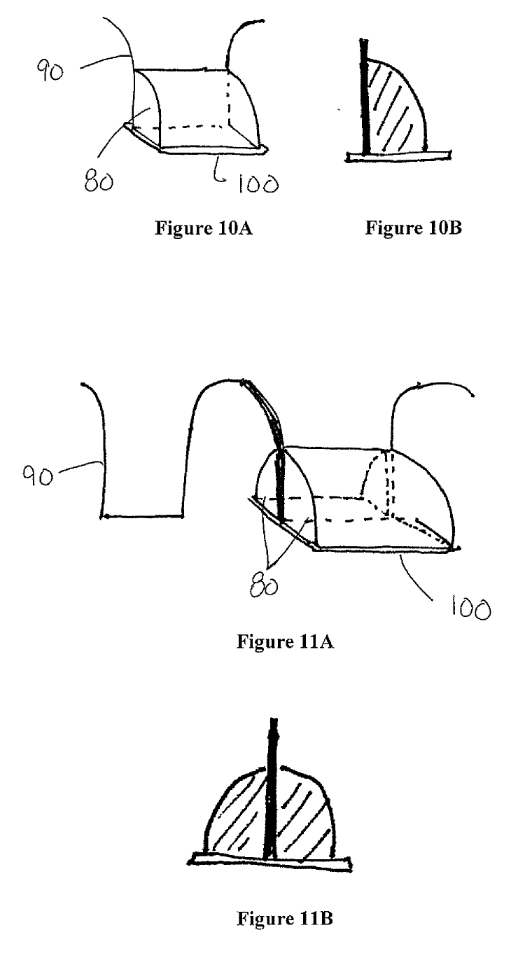

It can be seen that the solder 80 may be located and precisely positioned at various locations on the shield leg(s) 90 depending on the needs of the user. For example, as shown in FIGS. 9A and 9B, 10A and 10B, and 11A and 11B, the solder may be positioned on an inner surface of the leg(s) (FIGS. 9A and 9B), an outer surface of the leg(s) (FIGS. 10A and 10B) and both the inner and outer surfaces of the leg (FIGS. 11A and 11B). Furthermore, it is noted that the “inner surface” refers to the side of leg that is interior to the cavity of the shield when the shield is positioned over the substrate and the “outer surface” refers to the side of the leg that is exterior to the cavity of the shield when the shield is positioned over the substrate.

In addition, it will be appreciated that while the shield preferably has a rectangular shape, it will be understood that the shield is not limited to this shape. Thus, the shield can have any number of other shapes, including a square, an oval, etc. The dimensions and volume of the interior space of the shield should be sufficient to cover and shield the sensitive elements when the shield is mounted to the electronic component (i.e., PCB).

Given the task of designing an electromagnetic interference (EMI) shielded enclosure for a circuit board, understanding the balance between cost and performance is essential. There are many key decision points to be aware of during the design process including, galvanic compatibility, conductivity, the applications environment and how it relates to concerns with corrosion, material thickness, enclosure geometry (especially the shield height and how it relates to formability), application frequencies, packaging, and assembly of the shield onto the mating circuit board. Thus both the geometry of the shield and the shield construction material must be selected to produce the optimum result.

Some of the most common metals include tin and nickel plated steel in both bright and matte finishes, copper and copper alloys and aluminium. One preferred material is copper alloy 770 (also known as nickel silver).

Pre-tin plated steel works well from lower frequencies in the kHz range through frequencies into the lower GHz range. Carbon steel has a permeability value in the lower hundreds range which provides low-frequency magnetic shielding property. The tin plating offers corrosion protection for the steel to prevent rusting as well as providing a good solderable surface to attach the shield to the traces on the surface board during assembly.

Copper alloy 770, more commonly known as alloy 770, is a copper, nickel, zinc alloy used in EMI shielding applications mainly for its corrosion resistant properties. The alloy's unified numbering system designation is UNS C77000. The base material does not require post plating to make it corrosion resistant or solderable. The material works well as an EMI shield beginning in the mid kHz range up into the GHz. The permeability is 1 which makes it ideal in MRI related applications where magnetic materials are not permitted.

Copper is one of the most reliable metals in EMI shielding because it is highly effective in attenuating magnetic and electrical waves. Due to its versatility, copper can be easily fabricated along with its alloys brass, phosphorous bronze, and beryllium copper. These metals typically cost more than the alternative shielding alloys of pre-tin plated steel or copper alloy 770 but, on the other hand, offer a higher conductivity. Phosphorous bronze and beryllium copper are more commonly used in contact applications for batteries or springs due to their elasticity.

Although aluminum poses a few fabrication challenges, it is still a good choice for a number of applications mostly due to its non-ferrous properties, its strength-to-weight ratio, and its high conductivity. Aluminum has nearly 60 percent of conductivity when compared with copper; however, using this metal needs precise attention to its galvanic corrosion and oxidation properties. The material will form a surface oxide over time and has poor solderability on its own.

Other suitable solderable metals and alloys may also be used, depending on the specific needs of the customer.

The solder is preferably a suitable lead-free solder, such as SAC 305 (a lead-free solder that contains 96.5% tin, 3% silver, and 0.5% copper). However, other lead-free solders are also usable in the practice of the invention. The only technical limitation is that the solder wets to the shield material and is capable of forming an intermetallic bond or a diffusion bond, which can be overcome by plating with nickel, silver or tin. Many applications involving consumer electronics require Restriction of Hazardous Substances (RoHS) compliant solder materials, which do not contain lead, cadmium or other heavy metals. Typical RoHS compliant solders used in consumer electronics including, tin silver copper (i.e., SnAgCu), typically referred to as SAC, with melting ranges of about 212 to about 230° C. Typical examples include Sn—Ag3.0-Cu0.5 (SAC305), Sn—Ag4.0-Cu0.5 (SAC405), and low or zero silver versions. One emerging lower temperature RoHS-compliant solder family is tin bismuth silver (SnBiAg), with melting ranges of about 138 to about 190° C. Other related alloys include tin bismuth silver copper (SnBiAgCu). All of these solder materials are viable for loading solder onto a shield and for soldering the shield to a PCB. It is also conceivable to use non-RoHS solders, for example, in applications that have a RoHS exemption.

Other alloys include lead-containing alloys, including SnPb, SnPbAg, PbAgIn and PbAgSn, by way of example and not limitation. Examples of these include the following:

| Alloy | Melting Temp. ° C. |
|---|---|
| Sn63—Pb37 | 183 |
| Sn62—Pb36—Ag2 | 179 |
| Pb92.5—Ag2.5—In5 | 300 |
| Pb92.5—Ag2.5—Sn5 | 287-296 |
| Pb88—Ag2—Sn10 | 268-299 |

Other alloys including brazing alloys that generally contain AgCu, AgCuIn, AgCuZn, AgCuSnZn, by way of example and not limitation. Examples of these include the following:

| Alloy | Melting Temp. ° C. |
|---|---|
| Ag71.7—Cu28—Li0.3 | 760 |
| Ag61.5—Cu24—In14.5 | 625-705 |
| Ag50—Cu50 | 780-870 |
| Ag25—Cu40—Sn2—Zn33 | 690-780 |
| Ag35—Cu32—Zn33 | 685-755 |
| Ag38—Cu32—Sn2—Zn28 | 650-720 |
| Ag40—Cu30—Zn30 | 675-725 |
| Ag40—Cu30—Sn2—Zn28 | 650-710 |

Typically, since the shield is soldered to a PCB, and the solder alloy loaded on the shield is preferably matched with the intended PCB solder alloy, or be complementary to it, in that the loaded solder and the intended PCB solder used to attach the shield to the PCB mix, and form a new alloy. There are many combinations possible, but typically the solder is SAC or SnBi. It should be understood that the solder can be selected from any number of solder alloys, including lead containing and lead-free solder alloys, as well as other pure metals, such as tin.

The metallurgical bond is disposed between the interface of the shield and the solder. Thus, in one embodiment the solder used to create the intermetallic bond on the leg of the shield is the same as the solder used to attach the shield to the PCB. In this instance, preferred solders include SnAg, SnAgCu, SnBiAg, and SnBiAgCu, and similar lower cost solder alloys containing less silver.

In another embodiment, the solder used to create the intermetallic bond on the leg of the shield is different from but complementary with the solder used to attach the shield to the PCB, whereby a new solder alloy is formed in the reflow furnace when the shield and the PCB are joined together. In this instance the solder combinations used on the shield to create the metallurgical bond, and the solder used to join the shield to the PCB or other electronic component can be SnBi (shield) and SnAgCu (PCB), SnBiAg and SnAgCu, SnBiAgCu and SnAgCu. In the previous list pairs, the resultant alloy blend will have a lower melting temperature compared to SnAgCu used on the PCB, which would facilitate removal of the shield for repair without disturbing the previously formed solder joints on the PCB that connect integrated circuits. In a similar manner, the solder combinations, if they resulted in less total silver as a percentage compared to SnAg3.0Cu0.5 would be less prone to cracking when dropped (drop shock resistant).

It is noted that the solder for the PCB, typically delivered in the form of solder paste and stencil printing, would be primarily chosen based on the assembly requirements of the PCB and its electronic components, including the integrated circuits while the resultant blended solder for the shield attach to the PCB may be chosen to provide a different level of functionality, which could include lower melting point to support ease of rework, improved drop shock, improved thermal cycling resistance, and others, specifically targeting the shield attach requirements.

Other solder combinations, with the first listed being associated with the shield solder and the second associated with the PCB, are [SAC and SnBi, SAC and SnBiAg, SAC and SnBiAgCu], [SnAg and SnBi, SnAg and SnBiAg, SnAg and SnBiAgCu], [SACX and SnBi, SACX and SnBiAg, SACX and SnBiAgCu], where SACX refers to a specific low silver version of SAC, that also contains additives to improve solder features in the absence of a significant amount of silver, would rely on the dissolution of the SAC, SnAg or SACX alloy into the lower melting temperature PCB solders, namely SnBi, SnBiAG, and SnBiAgCu.

By adding more Sn to various SnBi versions, the ductility of the resultant alloy is improved. Increased ductility in solder has been shown to improve drop shock performance. From an assembly perspective, the PCB solder is uniform and is delivered with the use of solder paste and stencil printing, and is effected in a single process step. Adding the shield loaded with high Sn solder, and providing sufficient time in the reflow oven, the melting temperature of the high Sn solder need not be achieved. Dissolution will occur, with the higher melting temperature alloy on the shield dissolving into the lower temperature solder from the solder paste on the PCB, while reflowing at the temperature of the lower temperature solder.

Temporary solder masks (polymer-based) and temporary dry film masking materials (such as those available from DuPont) can be used to control the resultant location of the solder on the one or more legs of the shield. The choice of which to use will be driven by cost, manufacturing infrastructure issues and solder location precision requirements. It is also possible to chemically and mechanically etch portions of the material so it will be more receptive or less receptive to solder wetting.

The solder attach methods disclosed herein improve location and volume accuracy, which is tuned independently on individual shield legs or other surfaces as required. In addition, the bonded solder, once disposed on the legs of the shield, can be shaped by various means, such as coining, milling, skiving, scarfing, and other methods. The ability to shape the bonded solder surfaces enables the shield to be positioned and secured to the substrate more easily, and with greater precision.

The shield produced can contain any alloy or metal effective for shield attach, and the choice of solder is not limited by the product implementation. In various embodiments, the metal body includes Alloy 770 and the solder is SAC 305.

Almost any combination of shield metal and solder alloy will work and will depend on the needs of the particular customer. There is no particular restriction on the type of solder that can be used with the various shield materials, provided that the shield material can accept solder or be plated so as to more easily accept solder. It may be desirable to start with a shield material that the customer has successfully soldered previously, which, by definition, would accept solder with the attach method described herein. This would allow a designer of the shield to define a wide variety of product variations suitable for their end application.

Also described herein is a method of achieving the solder volume control and selectivity of location.

Thus, in one embodiment and as described herein, the present invention also relates generally to a method of attaching a shield to a substrate, the method comprising the steps of:

a) screen printing the substrate with solder paste in a desired pattern, wherein the desired pattern comprises desired locations of one or one electronic components on the substrate and a desired location of the shield on the substrate;

b) placing the shield on the substrate at the desired location, wherein the shield comprises a metal body configured to be attached to the substrate and solder integral to a lower portion of the metal body, wherein a bond is created between the solder and the metal body; and thereafter

c) placing the shielded substrate into a reflow furnace to solder the shield to the substrate.

In some embodiments, mechanical methods may be used to modify the solder volume and position after it is applied in bulk to the shield. These mechanical methods include, for example, one or more of grinding, scarfing, skiving, milling and trimming. Any of these methods, alone or in combination would be suitable for modifying the solder volume and position after it is applied in bulk to the shield.

The method described herein creates a pattern, the pattern comprising surfaces where solder selectively will wet, and other surfaces where solder will not wet.

The process is a capable of integrating any solder alloy without limitation. In order to implement this product, it is desirable to protect surfaces sufficiently to encourage solder attachment. Surfaces may be created that do not encourage solder attachment. Techniques that create surfaces that do not encourage solder attachment include masking and surface modification, such as, for example, selective oxidation or nitride layer placement. Masking can be comprised of either organic or inorganic materials. These process steps enhance the shield material yet do not inhibit the ease of down-stream processes necessary to fabricate an economically viable shield. In addition, it does not inhibit the final shield functionality in any way. The final modified shield can be automatically handled with the identical ease as the basic shield without solder.

Since the shield will eventually be soldered to a PCB or substrate, typically the customer requirements call out a material that is solderable. The only restriction is that oxidation can sometimes inhibit wetting of solder. Typically, there are standard handling precautions to prevent excess oxidation if the material is excessively prone to oxide, such as nickel. Our attachment method can overcome typical oxidation levels.

In another embodiment, the present invention also relates generally to a method of making a shield capable of protecting electronic components from electromagnetic and radio frequency interference comprising a metal body and solder integral to a lower portion of the metal body, the method comprising the steps of:

a) selectively applying solder to the lower portion of the metal body;

b) creating a bond between the solder and the metal body; and

c) optionally, modifying the solder volume and position on the metal body by mechanical means selected from the group consisting of grinding, scarfing, skiving, milling, trimming and combinations of one or more of the foregoing;

wherein the shield with the solder integral to the lower portion of the metal body is capable of being soldered to a substrate.

As described herein, the modified shield is joined to the substrate by soldering of the modified shield to the substrate using a reflow furnace or other soldering means.

It is to be appreciated that embodiments of the shield and methods of securing shields discussed herein are not limited in application to the details of construction and the arrangement set forth herein. The shields and methods are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiment.

Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

When introducing elements of the present invention or the preferred embodiments(s) thereof, the articles “a”, “an”, “the” and “said” are intended to mean that there are one or more of the elements. The terms “comprising,” “including” and “having” are intended to be inclusive and mean that there may be additional elements other than the listed elements.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only.

What is claimed is:

1. A shield capable of protecting at least a portion of an electronic system from electromagnetic and radio frequency interference, the shield comprising:
a metal body configured to be attached to a substrate; and
solder integral to a lower portion of the metal body, wherein a bond is created between the solder and the metal body.

2. The shield according to claim 1, wherein the lower portion of the metal body comprises at least one leg configured to be attached to the substrate, the metallurgical bond is created on the at least one leg.

3. The shield of claim 1, wherein the metal body comprises a metal selected from the group consisting of tin plated steel, nickel plated steel, copper, copper alloy, aluminum, and combinations of one or more of the foregoing.

4. The shield of claim 3, wherein the solder is a lead-free solder.

5. The shield according to claim 4, wherein the lead-free solder is selected from the group consisting of tin silver, tin bismuth, tin silver copper, tin bismuth silver, and tin bismuth silver copper solders.

6. The shield according to claim 5, wherein the lead-free solder is a tin silver copper solder.

7. The shield according to claim 1, wherein the solder is shaped by a mechanical means selected from the group consisting of coining, milling, skiving, scarfing, and combinations of one or more of the foregoing.

8. The shield according to claim 2, wherein location of the solder and volume of the solder on the at least one leg are controlled.

9. The shield according to claim 8, wherein the solder is located at a distance from the end of the at least one leg.

10. The shield according to claim 8, wherein the solder is located on at least one of at least a portion of an inner surface of the at least one leg or at least a portion of an outer surface of the at least one leg.

11. The shield according to claim 1, wherein the bond created between the solder and the metal body is a metallurgical bond or a diffusion bond.

12. A method of attaching a shield to a substrate, wherein the shield is capable of protecting at least a portion of an electronic component from electromagnetic and radio frequency interference, the method comprising the steps of:
a) screen printing the substrate with solder paste in a desired pattern, wherein the desired pattern comprises desired locations of one or one electronic components on the substrate and a desired location of the shield on the substrate;
b) placing the shield on the substrate at the desired location, wherein the shield comprises a metal body configured to be attached to the substrate and solder integral to a lower portion of the metal body, wherein a bond is created between the solder and the metal body; and thereafter
c) placing the shielded substrate into a reflow furnace to solder the shield to the substrate.

13. The method according to claim 12, wherein electronic components are place in the desired location on the screen printed substrate prior to step b), and step c) also solders the electronic components to the substrate.

14. The method according to claim 12, wherein the substrate is a printed circuit board.

15. The method according to claim 12, wherein the lower portion of the metal body of the shield comprises at least one leg configured to be attached to the substrate, and wherein the bond is created between the solder and the at least one leg.

16. The method according to claim 15, wherein the bond is (a) a metallurgical bond created by proximity of the solder to the at least one leg and sufficient heat and time to bring the solder to a melting temperature of the solder; or (b) a diffusion bond created by heat and pressure.

17. The method according to claim 12, wherein the metal body of the shield comprises a metal selected from the group consisting tin plated steel, nickel plated steel, copper, copper alloy, aluminum, and combinations of one or more of the foregoing.

18. The method according to claim 12, wherein the solder screen-printed onto the substrate is a lead-free solder.

19. The method according to claim 12, wherein the solder used to create the metallurgical bond on the shield is a lead-free solder selected from the group consisting of tin silver, tin bismuth, tin silver copper, tin bismuth silver, and tin bismuth silver copper solders.

20. The method according to claim 12, wherein the solder screen-printed onto the substrate is the same as the solder used to create the bond on the shield.

21. The method according to claim 12, wherein the solder screen-printed onto the substrate is compatible with the solder used to create the bond on the shield.

22. The method according to claim 21, wherein the solder screen-printed onto the substrate is different from the solder used to create the bond on the shield.

23. The method according to claim 12, wherein the solder on the shield is shaped by a mechanical means selected from the group consisting of coining, milling, skiving, scarfing, and combinations of one or more of the foregoing.

24. The method according to claim 12, comprising the step of controlling solder location on the shield by means of at least one of masking, etching, and nitride layer placement.

25. The method according to claim 24, wherein the solder is located at a distance from the end of the at least one leg.

26. The method according to claim 24, wherein the solder is located on at least one of at least a portion of an inner surface of the at least one leg or at least a portion of an outer surface of the at least one leg.

27. A method of making a shield capable of protecting electronic components from electromagnetic and radio frequency interference, the shield comprising a metal body and solder integral to a lower portion of the metal body, the method comprising the steps of:
a) selectively applying solder to the lower portion of the metal body;
b) creating a bond between the solder and the metal body; and
c) optionally, modifying the solder volume and solder position on the metal body by mechanical means selected from the group consisting of grinding, scarfing, skiving, milling, trimming and combinations of one or more of the foregoing;
wherein the shield with the solder integral to the lower portion of the metal body is capable of being soldered to a substrate.

28. The method according to claim 27, wherein the bond is (a) a metallurgical bond created by proximity of the solder to the at least one leg and sufficient heat and time to bring the solder to a melting temperature of the solder; or (b) a diffusion bond created by heat and pressure.

29. The method according to claim 27, wherein the location of the solder on the shield material is controlled by masking the shield material, etching the shield material or nitride layer placement on the shield material.

30. The method according to claim 29, wherein the solder is located at a distance from the end of the at least one leg.

31. The method according to claim 29, wherein the solder is located on at least one of at least a portion of an inner surface of the at least one leg or at least a portion of an outer surface of the at least one leg.

32. The method according to claim 27, wherein the solder is selectively applied to the shield by a method selected from the group consisting of printing, dispensing, placement, jetting and combinations of one or more of the foregoing.

33. A method of controlling location and volume of solder on a shield, wherein the shield is capable of protecting at least a portion of a substrate from electromagnetic and radio frequency interference, wherein the shield is solderable to the substrate, and wherein the shield comprises a metal body, wherein a lower portion of the metal body comprises at least one leg configured to be attached to the substrate, the method comprising the steps of:
a) creating areas for the selective application of solder on the shield, wherein the areas are created by one or more means selected from the group consisting of masking, etching, and nitride layer placement of the shield;
b) selectively applying solder to the areas created in step a), wherein the solder is applied by a method selected from the group consisting of printing, dispensing, placement, jetting and combination of one or more of the foregoing;
c) creating a bond between the solder and the metal body; and
d) optionally, modifying the solder volume and solder position on the metal body by mechanical means selected from the group consisting of grinding, scarfing, skiving, milling, trimming and combinations of one or more of the foregoing;
wherein the location and volume of solder on the shield is controlled.

34. The method according to claim 31, wherein the bond is (a) a metallurgical bond created by proximity of the solder to the at least one leg and sufficient heat and time to bring the solder to a melting temperature of the solder; or (b) a diffusion bond created by heat and pressure.

35. The method according to claim 33, wherein the solder is located at a distance from the end of the at least one leg.

36. The method according to claim 33, wherein the solder is located on at least one of at least a portion of an inner surface of the at least one leg or at least a portion of an outer surface of the at least one leg.
